(19) United States
(12) Patent Application Publication
(10) Pub. No.: US 2025/0297195 A1
(43) Pub. Date: Sep. 25, 2025

(54) ETCHING CLEANING COMPOSITION AND ETCHING CLEANING METHOD USING THE SAME

(71) Applicant: SOULBRAIN CO., LTD., Gyeonggi-do (KR)

(72) Inventors: Jae Sung LEE, Gyeonggi-do (KR); Chan Mi Kim, Gyeonggi-do (KR)

(21) Appl. No.: 19/078,828

(22) Filed: Mar. 13, 2025

(30) Foreign Application Priority Data
Mar. 19, 2024 (KR) 10-2024-0037683
Oct. 31, 2024 (KR) 10-2024-0151883

(51) Int. Cl. C11D 7/32; C11D 3/00; C11D 3/20; C11D 3/28; C11D 3/30; C11D 3/34; C11D 3/43; C11D 7/26; C11D 7/34; C11D 7/50; H01L 21/02

(52) U.S. Cl. CPC C11D 7/3209; C11D 3/0073; C11D 3/2086; C11D 3/28; C11D 3/30; C11D 3/3463; C11D 3/43; C11D 7/265; C11D 7/267; C11D 7/3245; C11D 7/3281; C11D 7/34; C11D 7/5013; H01L 21/02074

(57) ABSTRACT

The present invention relates to an etching cleaning composition and an etching cleaning method using the same. According to the present invention, the present invention has an effect of providing an etching cleaning composition capable of removing polishing residues generated when polishing surfaces where hybrid bonding between joints is required during semiconductor and display manufacturing processes and providing surface roughness and recesses appropriate for hybrid bonding; an etching cleaning method using the same; and a hybrid bonding material obtained using the same.

### TECHNICAL FIELD

The present invention relates to an etching cleaning composition and an etching cleaning method using the same. More particularly, the present invention relates to an etching cleaning composition capable of removing polishing residues generated when polishing surfaces where hybrid bonding between joints is required during semiconductor and display manufacturing processes and providing surface roughness and recesses appropriate for hybrid bonding; an etching cleaning method using the same; and a hybrid bonding material obtained using the same.

### BACKGROUND ART

The chemical mechanical polishing (hereinafter referred to as “CMP”) process is performed by applying a polishing slurry composition having active chemical properties to a polishing pad that rubs the surface of a semiconductor wafer. Polishing particles included in the polishing slurry composition and the surface protrusions of the polishing pad cause mechanical friction with the surface of the semiconductor wafer, thereby performing mechanical polishing, thereby effectively removing excess materials used in layer formation.

The chemical components included in the polishing slurry composition selectively remove the surface of the semiconductor wafer while inducing a selective chemical reaction on the surface of the semiconductor wafer.

Contamination occurs as a result of residues generated during CMP or particles resulting from removed layers. These residues or contaminants may cause wiring damage during various subsequent processes, such as forming metal wiring or various structures, etching, or die-to-die, die-to-wafer, or wafer-to-wafer recess bonding, so-called hybrid bonding. In addition, these residues or contaminants may cause damage to the structural surface, y directly cause poor electrical performance of semiconductor devices.

Accordingly, an additional cleaning operation is required to remove a significant amount of polishing residues present on the dielectric (dielectric layer surface) and metal electrode surface.

Therefore, there is a need to develop a technology for preparing an etching cleaning composition that can effectively perform the aforementioned cleaning operation while also implementing surface roughness and recesses appropriate for hybrid bonding.

### RELATED ART DOCUMENTS

### Patent Documents

KR 2022-0058414 A

### DISCLOSURE

### Technical Problem

Therefore, the present invention has been made in view of the above problems, and it is one object of the present invention to provide an etching cleaning composition capable of removing polishing residues generated when polishing surfaces where hybrid bonding between joints is required during semiconductor and display manufacturing processes and providing surface roughness and recesses appropriate for hybrid bonding; an etching cleaning method using the same; and a hybrid bonding material obtained using the same.

The above and other objects can be accomplished by the present invention described below.

### TECHNICAL SOLUTION

I) In accordance with one aspect of the present invention, provided is an etching cleaning composition having anisotropic pattern etching ability and surface zeta potential repulsive cleaning ability.

II) According to I), the surface zeta potential repulsive cleaning ability may be realized by making surface zeta potentials of a wafer and abrasive material negative (−).

III) According to I) to II), the etching cleaning composition may be a basic solution.

IV) According to I) to III), the etching cleaning composition may include an etching agent; a metal corrosion inhibitor; a silicon film etching inhibitor; a basic compound containing a hydroxyl group; and an alkanol amine compound.

V) According to I) to IV), the etching agent may be a compound containing a carboxyl group and having selective etching ability for copper, tungsten, or molybdenum.

VI) According to I) to V), the etching agent may include one or more selected from asparagine, ammonium citrate, glycine, arginine, histidine, lysine, alanine, citric acid, aspartic acid, and glutamic acid.

VII) According to I) to VI), based on a total weight of the etching cleaning composition, the etching agent may be included in an amount of 0.1 to 10% by weight.

VIII) According to I) to VII), the metal corrosion inhibitor may be a compound containing a functional group with strong reducing power and having corrosion inhibition properties of copper, tungsten, or molybdenum.

IX) According to I) to VIII), the metal corrosion inhibitor may include one or more selected from gallic acid, mercaptosuccinic acid, resorcinol, uric acid, vanillic acid, fructose, kojic acid, 5-aminosalicylic acid, and dextrose.

X) According to I) to IX), based on a total weight of the etching cleaning composition, the metal corrosion inhibitor may be included in an amount of 0.1 to 10% by weight.

XI) According to I) to X), the silicon film etching inhibitor may be a compound containing a sulfonic acid group and preventing etching of a dielectric substance.

XII) According to I) to XI), the dielectric substance may be silicon, a silicon oxide film, a silicon nitride film, a silicon carbon nitride film, or the like.

XIII) According to I) to XII), the silicon film etching inhibitor may include one or more selected from benzenesulfonic acid, sulfamic acid, 2,4-dimethylbenzenesulfonic acid, 4-hydroxypyridine-3-sulfonic acid, p-toluenesulfonic acid, ammonium sulfamate, and methanesulfonic acid.

XIV) According to I) to XIII), based on a total weight of the etching cleaning composition, the silicon film etching inhibitor may be included in an amount of 0.001 to 30% by weight.

XV) According to I) to XIV), the basic compound containing a hydroxyl group may be a compound having a hydroxyl group and adjusting pH of the etching cleaning composition to 8 or higher.

XVI) According to I) to XV), the basic compound containing a hydroxyl group may include one or more selected from tetramethylammonium hydroxide, tetraethylammonium hydroxide, tetrabutylammonium hydroxide, ammonium hydroxide, choline hydroxide, sodium hydroxide, and potassium hydroxide.

XVII) According to I) to XVI), based on a total weight of the etching cleaning composition, the basic compound containing a hydroxyl group may be included in an amount of 1 to 25% by weight.

XVIII) According to I) to XVII), the alkanol amine compound may include one or more selected from propanolamine, ethanolamine, diethanolamine, triethanolamine, 2-2-(ethylamino)ethanol, 1-amino-2-propanol, 2-(methylamino)ethanol, N,N-dimethylethanolamine, 1,3-diamino-2-propanol, 2-amino-1,3-propanediol, and 2-amino-2-methyl-1-propanol.

XIX) According to I) to XVIII), based on a total weight of the etching cleaning composition, the alkanol amine compound may be included in an amount of 0.1 to 10% by weight.

XX) According to I) to XIX), the etching cleaning composition may include one or more surfactants selected from a nonionic surfactant and an anionic surfactant.

XXI) According to I) to XX), based on a total weight of the etching cleaning composition, the surfactant may be included in an amount of 0.001 to 3% by weight.

XXII) According to I) to XXI), the etching cleaning composition may have a pH of 8 to 14.

XXIII) In accordance with another aspect of the present invention, provided is an etching cleaning method including removing polishing residues generated after a CMP process using the etching cleaning composition and forming surface roughness and recesses appropriate for hybrid bonding.

XXIV) According to XXIII), the etching and cleaning treatment may be direct treatment and/or indirect treatment.

XXV) According to XXIII) to XXIV), the direct treatment may be continuous immersion or batch immersion.

XXVI) According to XXIII) to XXV), the indirect treatment may be padding treatment or brush treatment.

XXVII) According to XXIII) to XXVI), through the etching and cleaning treatment, the metal electrode may be etched at a length of 50 Å or less per minute, and at the same time, polishing residues present on surfaces of the dielectric substance and the metal electrode surface may be removed.

XXVIII) In accordance with yet another aspect of the present invention, provided is a hybrid bonding material including preparing and polishing a semiconductor device or display device that requires hybrid bonding; and etching and cleaning the polished wafer using the etching cleaning composition described above,
wherein the metal electrode has an anisotropic etching pattern, and change in surface roughness of the dielectric substance before and after etching cleaning is −0.01 nm or more, preferably +0.01 nm or more.

XXIX) According to XXVIII), the metal electrode may have a surface roughness of 0.1 to 1.2 nm.

### Advantageous Effects

The etching cleaning composition according to the present invention can provide both anisotropic pattern etching ability and surface zeta potential repulsive cleaning ability, thereby simultaneously performing etching and cleaning treatment for semiconductor and display devices requiring hybrid bonding, thereby improving process efficiency and productivity.

In addition, the surface roughness of the dielectric surface and the metal electrode surface of the hybrid bonding material is excellent, and an appropriate recess for hybrid bonding is formed, so the composition is excellent as a bonding material.

### DESCRIPTION OF DRAWINGS

FIG. 1 is a schematic diagram showing the polished surface of a semiconductor device or display device requiring hybrid bonding according to conventional technology.

FIG. 2 is a schematic diagram showing a process for obtaining a hybrid bonding material by treating the conventional polished surface of FIG. 1 with an etching cleaning composition according to an embodiment of the present invention.

### BEST MODE

The present invention is described in detail below, but the present invention is not limited thereto.

In the present invention, the term “hybrid bonding” refers to bonding between different materials unless otherwise specified, and is mainly used in semiconductor products or display products.

In the present invention, the term “etching cleaning composition” refers to a composition applied to an application requiring both etching ability and cleaning ability, unless otherwise specified, but in the case of a post-polishing treatment process, the etching cleaning composition may also be used for an application requiring only etching or only cleaning.

The present inventors studied an etching cleaning composition capable of cleaning and removing polishing residues existing on the surfaces of a dielectric substance and a metal electrode during the polishing post-processing process among semiconductor and display manufacturing processes while forming a recess in the metal electrode. During the above study, the inventors confirmed that when combined with a specific composition in a certain pH range, all of the objectives could be achieved. Based on these results, the present inventors conducted further studies to complete the present invention.

The etching cleaning composition according to embodiments of the present invention is a post-polishing treatment composition and has anisotropic pattern etching ability and surface zeta potential repulsive cleaning ability.

In this case, etching and cleaning treatments for semiconductor and display devices requiring hybrid bonding may be performed simultaneously. In addition, the surface roughness of dielectric substance surface and metal electrode surface of a hybrid bonding material may be excellent, and the etching cleaning composition is suitable as a bonding material by forming appropriate recesses for hybrid bonding.

The surface zeta potential repulsive cleaning ability may be realized by making surface zeta potentials of a wafer and abrasive material negative (−). In this case, the removal effect may be maximized by cleaning with the electric force of repulsion.

The etching cleaning composition is preferably a basic solution so that the surface zeta potential of each of the wafer and the abrasive becomes negative (−).

The etching cleaning composition may include an etching agent; a metal corrosion inhibitor; a silicon film etching inhibitor; a basic compound containing a hydroxyl group; and an alkanol amine compound.

The etching agent may be a compound that contains a carboxyl group and performs the function of selectively etching copper, tungsten, or molybdenum.

For example, the etching agent may include one or more selected from asparagine, ammonium citrate, glycine, arginine, histidine, lysine, alanine, citric acid, aspartic acid, and glutamic acid, as a specific example, ammonium citrate and citric acid.

For example, based on a total weight of the etching cleaning composition, the etching agent may be included in an amount of 0.1 to 10% by weight, as a specific example, 1 to 10% by weight, as a preferred example, 1 to 5% by weight. In this case, the role of selectively etching copper, tungsten, or molybdenum may be maximized without affecting other effects.

The metal corrosion inhibitor may be a compound that contains a functional group with strong reducing power and acts to prevent corrosion of copper, tungsten or molybdenum.

For example, the metal corrosion inhibitor may include one or more selected from gallic acid, mercaptosuccinic acid, resorcinol, uric acid, vanillic acid, fructose, kojic acid, 5-aminosalicylic acid, and dextrose, as a specific example, uric acid, ascorbic acid, and the like.

For example, based on a total weight of the etching cleaning composition, the metal corrosion inhibitor may be included in an amount of 0.1 to 10% by weight, as a specific example, 0.1 to 5% by weight, as a preferred example, 0.1 to 3% by weight. In this case, the effect of preventing corrosion of copper, tungsten or molybdenum may be maximized without adversely affecting other effects.

The silicon film etching inhibitor may be a compound that contains a sulfonic acid group and plays a role in preventing etching of a silicon film.

Here, the dielectric substance may be silicon, a silicon oxide film, a silicon nitride film, a silicon carbon nitride film, or the like, unless otherwise specified.

For example, the silicon film etching inhibitor may include one or more selected from benzenesulfonic acid, sulfamic acid, 2,4-dimethylbenzenesulfonic acid, 4-hydroxypyridine-3-sulfonic acid, p-toluenesulfonic acid, ammonium sulfamate, and methanesulfonic acid, as a specific example, methanesulfonic acid, without being limited thereto.

For example, based on a total weight of the etching cleaning composition, the silicon film etching inhibitor may be included in an amount of 0.001 to 30% by weight, as a specific example, 0.1 to 5% by weight, as a preferred example, 0.1 to 3% by weight. In this case, the role of preventing etching of a silicon film may be maximized without affecting other effects.

For example, the basic compound containing a hydroxyl group may be a compound that adjusts the pH of the etching cleaning composition to 8 or higher.

For example, the basic compound containing a hydroxyl group may include one or more selected from tetramethylammonium hydroxide, tetraethylammonium hydroxide, tetrabutylammonium hydroxide, ammonium hydroxide, choline hydroxide, sodium hydroxide, and potassium hydroxide, as a specific example, tetramethylammonium hydroxide, tetraethylammonium hydroxide, and the like.

For example, based on a total weight of the etching cleaning composition, the basic compound containing a hydroxyl group may be included in an amount of 1 to 25% by weight, as a specific example, 5 to 20% by weight, as a preferred example, 8 to 20% by weight. In this case, by adjusting the pH of the etching cleaning composition to alkaline without affecting other effects, cleaning may be performed by repulsion by making the surface zeta potential of each of a wafer and abrasive material negative (−). In addition, the disadvantage of copper being over-etched when the pH is neutral or acidic may be resolved.

In the etching cleaning composition of the present invention, the alkanol amine compound may play a role in decomposing polishing residues present on the surfaces of the dielectric substance and metal electrode.

The alkanol amine is a substance commonly used as a pH regulator in this technical field, but in the case of the present invention, unlike the above, when the pH is neutral or acidic, copper over-etching occurs, so the alkanol amine is composed in a more basic environment. In particular, the alkanol amine is a substance that is difficult to provide at a pH (strongly basic environment) of 12 or higher and 14 or lower as required by the present invention even when added in excess.

For example, the alkanol amine compound may include one or more selected from propanolamine, ethanolamine, diethanolamine, triethanolamine, 2-2-(ethylamino)ethanol, 1-amino-2-propanol, 2-(methylamino)ethanol, N,N-dimethylethanolamine, 1,3-diamino-2-propanol, 2-amino-1,3-propanediol, and 2-amino-2-methyl-1-propanol, as a specific example, ethanolamine.

For example, based on a total weight of the etching cleaning composition, the alkanol amine compound may be included in an amount of 0.1 to 10% by weight, as a specific example, 1 to 10% by weight, as a preferred example, 3 to 8% by weight. In this case, the role of decomposing polishing residues present on the surfaces of the dielectric substance and metal electrode may be maximized without affecting other effects.

The etching cleaning composition may further include a surfactant.

The surfactant may include one or more selected from a nonionic surfactant and an anionic surfactant.

For example, the nonionic surfactant may be a copolymer including polyethylene glycol, polypropylene glycol, polyoxyethylene oxide, polyalkyl oxide, polyethylene oxide, polyoxyethylene sorbitol hexaoleate, polyoxyethylene sorbitol tetraoleate, polyoxyethylene lauryl ether, polyoxylethylene octylphenyl ether, dodecenyl succinic acid monodiethanol amide, and alkyl polyglucoside; or TERGITOL™ TMN-6, TERGITOL™ 15-S-5, or TERGITOL™ NP-40 (Dow Co.), or the like.

For example, the anionic surfactant may be a copolymer including alkyl ether phosphate, aryl ether phosphate, ammonium lauryl sulfate, sodium dodecyl benzene sulfonate, ammonium dodecyl benzene sulfonate, sodium polyoxyethylene alkyl aryl sulfate, ammonium polyoxyethylene alkyl sulfate, disodium laureth sulfosuccinate, and sodium lauryl polyoxyethylene ether sulfate; or TERGITOL™ W-610, TRITON™ H-11, or TRITON™ DF-20 (Dow Co.), or the like.

For example, based on a total weight of the etching cleaning composition, the surfactant may be included in an amount of 0.001 to 3% by weight, as a specific example, 0.001 to 1% by weight, as a preferred example, 0.001 to 0.02% by weight. In this case, polishing residues present on the surfaces of the dielectric substance and metal electrode may be efficiently cleaned without adversely affecting the etching cleaning composition provided.

For example, the etching cleaning composition may have a pH of 8 to 14, as a specific example, 9 to 14, preferably 12 to 14. In this case, as a post-polishing treatment composition, an etching cleaning composition having anisotropic pattern etching ability and surface zeta potential repulsive cleaning ability may be effectively provided.

The target materials to be cleaned in the present invention may include abrasive materials used in polishing, pad debris, and various polishing residues that may be generated during the process.

As the abrasive material, various materials known in this technical field may be used, for example, silica, ceria, etc.

The target material to be etched in the present invention may be copper, tungsten or molybdenum.

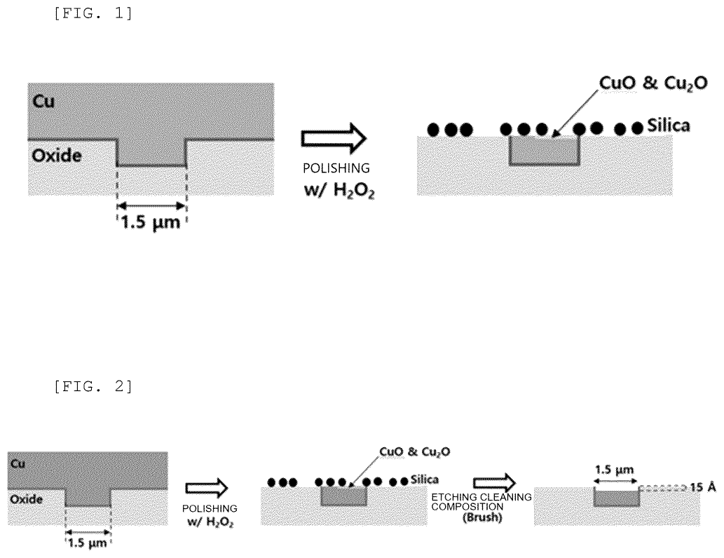

For example, FIGS. 1 and 2 below show a surface after conventional polishing and a surface subjected to post-polishing treatment, respectively, and the post-polishing treatment is performed using the etching cleaning composition of the present invention.

Specifically, FIG. 1 below is a schematic diagram showing the polished surface of a semiconductor device or display device requiring hybrid bonding, and FIG. 2 below is a schematic diagram showing a process for obtaining a hybrid bonding material by treating with the etching cleaning composition according to one embodiment of the present invention of FIG. 1.

As shown in FIG. 1 below, it can be confirmed that polishing residues were generated on both the dielectric substance, which is an abrasive material, and the metal electrode after the CMP process. In addition, it can be confirmed that metal oxide film(s) (CuO & Cu₂O shown in FIGS. 1 and 2) were generated on the metal electrode.

As shown in FIG. 2 below, when post-polishing treatment is performed using the etching cleaning composition according to the present invention after the CMP process, it can be confirmed that polishing residues remaining on the dielectric substance and metal electrode are removed, and at the same time, all metal oxide films observed on the metal electrode are removed, and surface roughness and recesses appropriate for hybrid bonding are formed.

Here, the etching removal of the metal electrode may be controlled in angstrom (Å) units by controlling the composition content, dilution ratio, and process time. In fact, the metal electrode has an anisotropic pattern, which may have a width of 15 μm on one side and a depth of 15 Å, without being not limited thereto.

In addition, the present invention provides an etching cleaning method including a step of etching and cleaning a wafer and an abrasive material using the etching cleaning composition described above.

The etching and cleaning treatment may be direct treatment and/or indirect treatment.

The direct treatment may be continuous immersion or batch immersion, and any method commonly used in this technical field may be used. Since the direct treatment is well known in the art, a detailed description thereof is omitted.

The indirect treatment may be padding treatment, or brush treatment, and any method commonly used in this technical field may be used. Since the indirect treatment is well known in the art, a detailed description thereof is omitted.

Through the etching and cleaning treatment, the metal electrode may be etched at a length of 50 Å or less per minute, and at the same time, polishing residues present on surfaces of the dielectric substance and the metal electrode surface may be removed.

Specifically, the etching rate for a metal electrode included in a semiconductor device or a display device is 50 Å/min or less, the depth of a joint recess on the metal electrode is 10 to 30 Å, and the change in surface roughness of a dielectric substance before and after etching cleaning is −0.01 nm or more, preferably +0.01 nm or more.

In addition, the effect of removing 99% or more or all of polishing residues present on the surfaces of the dielectric substance and metal electrode included in the semiconductor device or display device may be obtained.

Here, the semiconductor device refers to a semiconductor memory device such as DRAM, NAND, and especially HBM (high-bandwidth memory) and GDDR (graphic double data rate); a system semiconductor device such as CPU (central process unit) and AP (application processor); or a heterojunction semiconductor device thereof, without being limited thereto.

In addition, the display device refers to an image sensor such as CIS (CMOS image sensor), without being limited thereto.

In addition, the present invention provides a hybrid bonding material including a step of preparing and polishing a semiconductor device or display device that requires hybrid bonding; and a step of etching and cleaning the polished abrasive material and a wafer using the etching cleaning composition described above, wherein the metal electrode has an anisotropic etching pattern, and the change in surface roughness of the dielectric substance before and after etching cleaning is −0.01 nm or more, preferably +0.01 nm or more.

When etching and/or cleaning treatment is performed with a conventional wet composition, an isotropic etching pattern is obtained. However, when the etching cleaning composition of the present invention is used, the etching rate of the metal electrode is very low, providing an advantage of obtaining an anisotropic etching pattern.

The metal electrode may have a roughness of 0.1 to 1.2.

The change in surface roughness of the dielectric substance before and after etching cleaning may be −0.01 nm or more, preferably +0.01 nm or more.

In particular, in the case of conventional polishing slurry, it is difficult to control the selectivity for the polishing speed of the dielectric substance and Cu, making it impossible to control proper dishing of copper via. When the polishing speed of the dielectric substance is too fast compared to the polishing speed of copper in the selectivity between the dielectric substance and copper, the desired dishing of the copper via electrode may not be formed, and thus the bonding process may not proceed. Conversely, when the polishing speed of copper is too fast, the dishing of the copper via electrode may be too deep, and the bonding of the copper via electrode may not be formed during the bonding process. Accordingly, the problem may be completely solved by providing a hybrid bonding joint material by using the etching cleaning composition of the present invention for etching cleaning.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### Examples 1 to 10, Comparative Examples 1 to 9

The etching cleaning compositions of Examples 1 to 10 and Comparative Examples 1 to 9 were prepared according to the compositions (wt % by weight) shown in Tables 1 to 6, respectively.

Each etching cleaning composition was dissolved in deionized water (Weight ratio of deionized water:etching cleaning composition of 100:1), and the cleaning solution prepared by dilution was adjusted to 25° C.

Each compound was used in wt % and included the remainder of water, and tetraethylammonium hydroxide (TEAH) was added at different wt % so that the pH of all formulations was 13, except for Comparative Example 7, which had a pH of 6, and Comparative Example 8, which had a pH of 11.5.

Using each prepared etching cleaning composition, 10 nm copper dishing for a silicon oxide film (SiO) and a copper electrode part and etching and cleaning experiments for the silicon oxide film (SiO) were performed, and the performance was evaluated.

The performance evaluation compared the etching rate of copper, the etching rate of silicon oxide film, the change in surface roughness of silicon oxide film (before and after), the cleaning power for silica abrasive material, and the cleaning power for organic residues using the immersion and brush scrubbing methods.

Each measurement method is as follows:

### <Etching Rate of Copper>

The thickness before and after copper evaluation was measured, and the etching rate of copper was calculated according to Equation 1 below.

$$[ Equation 1 ]$$

$$( ( Thickness before copper evaluation ) - ( Thickness after copper evaluation ) ) / Evaluation time [ Å / min ]$$

At this time, each thickness was measured using a surface resistance meter (CMT-SR5000, AITI Co.), and the specific experiment was performed as follows.

(1) After cutting copper into 2 cm×2 cm pieces, a copper oxide film was removed.

(2) Thickness before evaluation was measured using a surface resistance meter (CMT-SR5000, AITI Co.).

(3) Each cleaning solution was brought into contact with the copper for a certain period of time by immersion or brush scrubbing, then the copper was rinsed with pure water and the surface was dried using nitrogen gas.

(4) After evaluation, the copper thickness was measured using a surface resistance meter (CMT-SR5000, AITI Co.), and the etching rate was calculated according to Equation 1.

### <Etching Rate of Silicon Oxide Film>

The thickness before and after silicon oxide film evaluation was measured, and the etching rate of the silicon oxide film was calculated according to Equation 2 below.

$$[ Equation 2 ]$$

$$( ( Thickness before silicon oxide film evaluation ) - ( Thickness after silicon oxide film evaluation ) ) / Evaluation time [ Å / min ]$$

At this time, each thickness was measured using an ellipsometer (M-2000, Ulam Co.), and the specific experiment was performed as follows.

(1) After cutting the silicon oxide film into 2 cm×2 cm pieces, the natural oxide film was removed.

(2) The thickness before evaluation was measured using an ellipsometer.

(3) Each cleaning solution was brought into contact with the silicon oxide film for a certain period of time by immersion or brush scrubbing, then the silicon oxide film was rinsed with pure water, and the surface was dried using nitrogen gas.

(4) The thickness of the silicon oxide film after evaluation was measured using an ellipsometer (M-2000, Ulam Co.), and the etching rate of the silicon oxide film was calculated according to Equation 2.

The evaluation of the silicon carbon nitride film (SiCN) in Table 7 described below was also conducted in the same manner as the <Etching rate of silicon oxide film>evaluation above.

### <Change in Surface Roughness of Silicon Oxide Film>

The surface roughness of the silicon oxide film before and after evaluation was measured at the center of a 2 cm×2 cm coupon wafer, and the change in surface roughness of the silicon oxide film was calculated according to Equation 3 below. For reference, three measurements were taken near the center of the wafer and then averaged.

$$[ Equation 3 ]$$

$$( Surface roughness before silicon oxide film evaluation ) - ( Surface roughness after silicon oxide film evaluation )$$

Calculated value of Equation 3<−0.01 nm: Increased surface roughness,
Calculated value of Equation 3>+0.01 nm: Reduced surface roughness,
When the calculated value of Equation 3 is −0.01˜+0.01 nm: No change

The surface roughness of the silicon oxide film was analyzed using an atomic force microscope (XE15, Park Systems Co.), and the specific experiments were performed as follows.

(1) The silicon oxide film wafer was cut into 2 cm×2 cm pieces, and a natural oxide film was removed.

(2) The surface roughness before evaluation was measured using an atomic force microscope.

(3) Each cleaning solution was brought into contact with the silicon oxide film for a certain period of time by immersion or brush scrubbing, then the silicon oxide film was rinsed with pure water, and the surface was dried using nitrogen gas.

(4) The surface roughness of the silicon oxide film after evaluation was measured using an atomic force microscope, and the change in surface roughness of the silicon oxide film was calculated according to Equation 3.

The evaluation of the silicon carbon nitride film (SiCN) in Table 7 described below was also conducted in the same manner as the <Change in surface roughness of silicon oxide film>evaluation above.

### <Cleaning Power for Silica Abrasive Material on Copper>

The cleaning power for a silica abrasive material on copper was measured nine times at the center, each corner, and the midpoint between the center and each corner of a 2 cm×2 cm coupon wafer, and the average was calculated, and then calculated according to Equation 4 below.

$$[ Equation 4 ]$$

$$( Area of silica abrasive material when contaminated with silica abrasive material after evaluation ) / ( Area of silica abrasive material when contaminated with silica abrasive material ) \times 100 ( \% ) ; Particle removal efficiency ( PRE )$$

### O: 99.5% or More, Δ: 99.0˜99.5%, X: 99.0% Or Less

At this time, the silica abrasive material present on the copper surface was analyzed using a scanning electron microscope (S4800, Hitachi Co.), and the specific experiment was performed as follows.

(1) After cutting the copper wafer into 2 cm×2 cm pieces, pretreatment was performed.

(2) After immersing into the abrasive material containing the silica abrasive material to simulate silica contamination, the area of the silica abrasive material was calculated relative to the analysis area using a scanning electron microscope and the Image J program. After loading the scanning electron microscope image into Image J, the contrast was adjusted to obtain the area value of the silica abrasive material.

(3) Each cleaning solution was brought into contact with the copper film for a certain period of time by immersion or brush scrubbing, then the copper film was rinsed with pure water, and the surface was dried using nitrogen gas.

(4) After evaluation, the area of silica remaining on the copper surface was calculated using the contrast ratio using the Image J program.

(5) The cleaning power for the silica abrasive material on copper was calculated according to Equation 4.

### <Cleaning Power for Silica Abrasive Material on Silicon Oxide Film>

The cleaning power for a silica abrasive material on a silicon oxide film was measured nine times at the center, each corner, and the midpoint between the center and each corner of a 2 cm×2 cm coupon wafer, and the average was calculated, and then calculated according to Equation 5 below.

$$[ Equation 5 ]$$

$$( Area of silica abrasive material when contaminated with silica abrasive material ) - ( Area of silica abrasive material after evaluation ) / ( Area of silica abrasive material when contaminated with silica abrasive material ) \times 100 ( \% ) ; Partical removal efficiency ( PRE )$$

### O: 99.0% or More, Δ: 97.0˜99.0%, X: 97.0% or Less

At this time, the silica abrasive material present on the silicon oxide film surface was analyzed using a scanning electron microscope (S4800, Hitachi Co.), and the specific experiment was performed as follows.

(1) After cutting the silicon oxide film into 2 cm×2 cm pieces, pretreatment was performed.

(2) After immersing into the abrasive material containing the silica abrasive material to simulate silica contamination, the area of the silica abrasive material was calculated relative to the analysis area using a scanning electron microscope and the Image J program.

(3) Each cleaning solution was brought into contact with the silicon oxide film for a certain period of time by immersion or brush scrubbing, then the silicon oxide film was rinsed with pure water, and the surface was dried using nitrogen gas.

(4) After evaluation, the area of silica remaining on the silicon oxide film surface was calculated using the contrast ratio using the Image J program.

(5) The cleaning power for the silica abrasive material on the silicon oxide film was calculated according to Equation 5.

The same evaluation was conducted on the silicon carbon nitride film (SiCN) of Table 7 described below.

### <Cleaning Power for Organic Residues>

The cleaning power for organic residues on copper and a silicon oxide film surface was measured nine times at the center, each corner, and the midpoint between the center and each corner of a 2 cm×2 cm coupon wafer, and the average was calculated, and then calculated according to Equation 6 below.

(Number of organic particles remaining after organic matter cleaning) [Equation 6]

### O: 0 EA, Δ: 50 EA or Less, X: 50 EA or More

Organic particles present on the copper and silicon oxide film surface were analyzed using an optical microscope and a scanning electron microscope (KH-8700, Hyrox Co.).

(1) After cutting copper or a silicon oxide film into 2 cm×2 cm pieces, pretreatment was performed.

(2) After adding organic powder to IPA, the organic powder was sprayed onto each film.

(3) Each cleaning solution was brought into contact with the copper or silicon oxide film for a certain period of time by immersion or brush scrubbing, then the copper or silicon oxide film was rinsed with pure water, and the surface was dried using nitrogen gas.

(4) After evaluation, the number of organic particles remaining on the copper or silicon oxide film surface was counted, and was recorded in the following tables.

The same evaluation was conducted on the silicon carbon nitride film (SiCN) of Table 7 described below, and the results were recorded in the tables.

### <Confirmation of Copper Oxide Film Formation>

To confirm whether an oxide film was formed on copper after evaluation, the intensities of copper (Cu) and oxygen (O) elements were confirmed using an X-ray fluorescence spectrometer (XRF, ZSX Primus 400, Rigaku Co.).

(1) After cutting a copper wafer into 2 cm×2 cm pieces, pretreatment was performed.

(2) The intensities of copper and oxygen were determined using an energy-dispersive X-ray fluorescence spectrometer before evaluation.

(3) Immersion in each cleaning solution was performed for 1 hour.

(4) After evaluation, the intensities of copper and oxygen were confirmed and recorded in the following tables.

TABLE 1

| Composition (wt %, | | | | | |
|---|---|---|---|---|---|
| Residual amount: | | Example | Example | Example | Example |
| Ultrapure water) | Compounds | 1 | 2 | 3 | 4 |
| Etching | Citric acid | 5.0 | | | |
| agent | Ammonium | | 1.0 | | |
| | citrate | | | | |
| | Glycine | | | 1.0 | |
| | Arginine | | | | 1.0 |
| Metal | Uric acid | 1.5 | 1.5 | 1.5 | 1.5 |
| corrosion | Kojic acid | | | | |
| inhibitor | Ascorbic acid | | | | |
| Silicon | MSA | 1.0 | 1.0 | 1.0 | 1.0 |
| film | Sulfamic acid | | | | |
| etching | Ammonium | | | | |
| inhibitor | sulfamate | | | | |
| Hydroxyl | Tetraethyl- | 18.8 | 12.6 | 12.4 | 11.8 |
| group- | ammonium | | | | |
| containing | hydroxide | | | | |
| basic | (TEAH) | | | | |
| compound | | | | | |
| Organic | Ethanolamine | 5.0 | 5.0 | 5.0 | 5.0 |
| solvent | (MEA) | | | | |

Immersion evaluation results

| Cu E/R [Å/min] | | 32.79 | 30.27 | 43.80 | 87.29 |
|---|---|---|---|---|---|
| Oxide E/R [Å/min] | | 0.14 | 0.09 | 0.12 | 0.18 |
| Oxide Roughness | | Decrease | No | No | Decrease |
| (Increase/decrease | | | change | change | |
| before/after evaluation) | | | | | |
| Cleaning | Cu | Δ | X | ◯ | Δ |
| power | Oxide | Δ | Δ | X | Δ |
| (Silica) | | | | | |
| Cleaning | Cu | ◯ | X | X | X |
| power | Oxide | ◯ | Δ | X | Δ |
| (Organic) | | | | | |

Brush scrubbing evaluation results

| Cu E/R [Å/min] | | 20.69 | 5.09 | 0.00 | 31.44 |
|---|---|---|---|---|---|
| Oxide E/R [Å/min] | | 0.00 | 0.12 | 0.00 | 0.00 |
| Oxide Roughness | | Decrease | Decrease | Decrease | No |
| (Increase/decrease | | | | | change |
| before/after evaluation) | | | | | |
| Cleaning | Cu | ◯ | X | X | X |
| power | Oxide | ◯ | Δ | Δ | ◯ |
| (Silica) | | | | | |
| Cleaning | Cu | ◯ | X | ◯ | X |
| power | Oxide | ◯ | ◯ | ◯ | ◯ |
| (Organic) | | | | | |

As shown in Table 1, the control of the etching rate of metal electrode (copper) according to the type of etching agent was confirmed.

In particular, in addition to the type of the etching agent, it was confirmed that the copper etching rate was controlled by adjusting the process conditions (time, temperature, cleaning method), etching agent content, and deionized water dilution ratio.

For example, in Example 1, during 30 seconds of immersion evaluation, a copper recess of 15 angstroms was formed, and during brush scrubbing evaluation, the copper etching rate was relatively low. These results are not considered to be due to fundamental performance differences, but rather to insufficient time being given to etch the copper. In addition, etching may not be performed properly during brush scrubbing depending on the polarity, hydrophilicity, and other characteristics of the component.

Accordingly, when sufficient copper recesses have been created by chemical polishing, the etching cleaning composition of Example 3 may be used to stop further copper etching.

TABLE 2

| Composition (wt %, | | | | |
|---|---|---|---|---|
| Residual amount: | | Example | Example | Example |
| Ultrapure water) | Compounds | 1 | 5 | 6 |
| Etching | Citric acid | 5.0 | 5.0 | 5.0 |
| agent | Ammonium | | | |
| | citrate | | | |
| | Glycine | | | |
| | Arginine | | | |
| Metal | Uric acid | 1.5 | | |
| corrosion | Kojic acid | | 1.5 | |
| inhibitor | Ascorbic acid | | | 1.5 |
| Silicon | MSA | 1.0 | 1.0 | 1.0 |
| film | Sulfamic acid | | | |
| etching | Ammonium | | | |
| inhibitor | sulfamate | | | |
| Hydroxyl | Tetraethyl- | 18.8 | 19.3 | 19.7 |
| group- | ammonium | | | |
| containing | hydroxide | | | |
| basic | (TEAH) | | | |
| compound | | | | |
| Organic | Ethanolamine | 5.0 | 5.0 | 5.0 |
| solvent | (MEA) | | | |

Immersion evaluation results

| Cu E/R [Å/min] | | 32.79 | 5.17 | 3.93 |
|---|---|---|---|---|
| Oxide E/R [Å/min] | | 0.14 | 0.03 | 0.26 |
| Oxide Roughness | | Decrease | No | Increase |
| (Increase/decrease | | | change | |
| before/after evaluation) | | | | |
| Cleaning | Cu | Δ | X | X |
| power | Oxide | Δ | Δ | Δ |
| (Silica) | | | | |
| Cleaning | Cu | ◯ | X | Δ |
| power | Oxide | ◯ | ◯ | X |
| (Organic) | | | | |

Brush scrubbing evaluation results

| Cu E/R [Å/min] | | 20.69 | 10.52 | 25.88 |
|---|---|---|---|---|
| Oxide E/R [Å/min] | | 0.00 | 0.00 | 0.00 |
| Oxide Roughness | | Decrease | Decrease | No |
| (Increase/decrease | | | | change |
| before/after evaluation) | | | | |
| Cleaning | Cu | ◯ | X | X |
| power | Oxide | ◯ | Δ | ◯ |
| (Silica) | | | | |
| Cleaning | Cu | ◯ | X | Δ |
| power | Oxide | ◯ | ◯ | ◯ |
| (Organic) | | | | |

As shown in Table 2, The effects of different types of metal corrosives were confirmed.

TABLE 3

| | Pure copper | Example | Example | Example |
|---|---|---|---|---|
| XRF Intensity | wafer | 1 | 5 | 6 |
| Cu | 1852.314 | 1798.824 | 1824.138 | 1774.988 |
| O | 0.13378 | 0.088942 | 0.087076 | 0.093016 |
| O/Cu | 0.00007 | 0.00005 | 0.00005 | 0.00005 |

As shown in Table 3, the intensities of copper (Cu) and oxygen (O) elements for a pure copper wafer and Examples 1, 5, and 6 were measured under vacuum conditions using a ZSX Primus 400 (Rigaku Co.) device. As a result, for all of Examples 1, 5, and 6, the oxygen intensity after evaluation decreased compared to the pure copper wafer, and the oxygen to copper (O/Cu) value decreased. These results indicate that a copper oxide film was not formed.

TABLE 4

| Composition (wt %, | | | | | |
|---|---|---|---|---|---|
| Residual amount: | | Example | Example | Example | Comparative |
| Ultrapure water) | Compounds | 1 | 7 | 8 | Example 1 |
| Etching | Citric acid | 5.0 | 5.0 | 5.0 | 5.0 |
| agent | Ammonium | | | | |
| | citrate | | | | |
| | Glycine | | | | |
| | Arginine | | | | |
| Metal | Uric acid | 1.5 | 1.5 | 1.5 | 1.5 |
| corrosion | Kojic acid | | | | |
| inhibitor | Ascorbic acid | | | | |
| Silicon | MSA | 1.0 | | | |
| film | Sulfamic acid | | 1.0 | | |
| etching | Ammonium | | | 1.0 | |
| inhibitor | sulfamate | | | | |
| Hydroxyl | Tetraethyl- | 18.8 | 18.5 | 18.4 | 13.9 |
| group- | ammonium | | | | |
| containing | hydroxide | | | | |
| basic | (TEAH) | | | | |
| compound | | | | | |
| Organic | Ethanolamine | 5.0 | 5.0 | 5.0 | 5.0 |
| solvent | (MEA) | | | | |

Immersion evaluation results

| Cu E/R [Å/min] | | 32.79 | 17.76 | 15.56 | 16.42 |
|---|---|---|---|---|---|
| Oxide E/R [Å/min] | | 0.14 | 0.25 | 0.29 | 0.08 |
| Oxide Roughness | | Decrease | Increase | Increase | Decrease |
| (Increase/decrease | | | | | |
| before/after evaluation) | | | | | |
| Cleaning | Cu | Δ | ◯ | X | X |
| power | Oxide | Δ | X | Δ | Δ |
| (Silica) | | | | | |
| Cleaning | Cu | ◯ | ◯ | Δ | ◯ |
| power | Oxide | ◯ | X | Δ | Δ |
| (Organic) | | | | | |

Brush scrubbing evaluation results

| Cu E/R [Å/min] | | 20.69 | −15.50 | 0.00 | 10.40 |
|---|---|---|---|---|---|
| Oxide E/R [Å/min] | | 0.00 | 0.05 | 0.08 | 0.13 |
| Oxide Roughness | | Decrease | No | No | Decrease |
| (Increase/decrease | | | change | change | |
| before/after evaluation) | | | | | |
| Cleaning | Cu | ◯ | ◯ | ◯ | Δ |
| power | Oxide | ◯ | ◯ | Δ | Δ |
| (Silica) | | | | | |
| Cleaning | Cu | ◯ | X | X | ◯ |
| power | Oxide | ◯ | Δ | X | ◯ |
| (Organic) | | | | | |

As shown in Table 4, the effectiveness of silicon oxide film etching inhibitor was confirmed in brush scrubbing evaluation.

TABLE 5

| Composition (wt %, | | | | |
|---|---|---|---|---|
| Residual amount: | | Example | Example | Example |
| Ultrapure water) | Compounds | 1 | 9 | 10 |
| Etching | Citric acid | 5.0 | 5.0 | 5.0 |
| agent | Ammonium | | | |
| | citrate | | | |
| | Glycine | | | |
| | Arginine | | | |
| Metal | Uric acid | 1.5 | 1.5 | 1.5 |
| corrosion | Kojic acid | | | |
| inhibitor | Ascorbic acid | | | |
| Silicon | MSA | 1.0 | 1.0 | 1.0 |
| film | Sulfamic acid | | | |
| etching | Ammonium | | | |
| inhibitor | sulfamate | | | |
| Hydroxyl | Tetraethyl- | 18.8 | 19.2 | 19.2 |
| group- | ammonium | | | |
| containing | hydroxide | | | |
| basic | (TEAH) | | | |
| compound | | | | |
| Organic | Ethanolamine | 5.0 | 5.0 | 5.0 |
| solvent | (MEA) | | | |
| Surfactant | Nonionic | | 0.01 | |
| | (TERGITOL ™TMN-6) | | | |
| | Anionic | | | 0.01 |
| | (TRITON ™DF-20) | | | |

Immersion evaluation results

| Cu E/R [Å/min] | | 32.79 | 20.04 | 17.20 |
|---|---|---|---|---|
| Oxide E/R [Å/min] | | 0.14 | 0.10 | 0.32 |
| Oxide Roughness | | Decrease | No | Decrease |
| (Increase/decrease | | | change | |
| before/after evaluation) | | | | |
| Cleaning | Cu | Δ | ◯ | ◯ |
| power | Oxide | Δ | Δ | Δ |
| (Silica) | | | | |
| Cleaning | Cu | ◯ | ◯ | ◯ |
| power | Oxide | ◯ | ◯ | Δ |
| (Organic) | | | | |

Brush scrubbing evaluation results

| Cu E/R [Å/min] | | 20.69 | 5.18 | 10.38 |
|---|---|---|---|---|
| Oxide E/R [Å/min] | | 0.00 | 0.25 | 0.03 |
| Oxide Roughness | | Decrease | Decrease | Decrease |
| (Increase/decrease | | | | |
| before/after evaluation) | | | | |
| Cleaning | Cu | ◯ | ◯ | Δ |
| power | Oxide | ◯ | Δ | Δ |
| (Silica) | | | | |
| Cleaning | Cu | ◯ | X | ◯ |
| power | Oxide | ◯ | ◯ | ◯ |
| (Organic) | | | | |

As shown in Table 5, a surfactant may be further added. In this case, the surface roughness of the silicon oxide film may be reduced, but a decrease in cleaning power was confirmed.

TABLE 6

| | | | Compar- | Compar- | Compar- | Compar- | Compar- | Compar- | Compar- | Compar- |
|---|---|---|---|---|---|---|---|---|---|---|
| | | | ative | ative | ative | ative | ative | ative | ative | ative |
| Composition (wt %, | | Exam- | Exam- | Exam- | Exam- | Exam- | Exam- | Exam- | Exam- | Exam- |
| Residual amount: | | ple | ple | ple | ple | ple | ple | ple | ple | ple |
| Ultrapure water) | Compounds | 1 | 2 | 3 | 4 | 5 | 6 | 7 | 8 | 9 |
| Etching | Citric | 5.0 | 5.0 | | | | | 5.0 | 5.0 | |
| agent | acid | | | | | | | | | |
| | Ammonium | | | | | | | | | |
| | citrate | | | | | | | | | |
| | Glycine | | | | | | | | | |
| | Arginine | | | | | | | | | |
| | Hydrogen | | | | | | | | | 5.0 |
| | peroxide | | | | | | | | | |
| Metal | Uric acid | 1.5 | | 1.5 | | | | 1.5 | 1.5 | 1.5 |
| corrosion | Kojic | | | | | | | | | |
| inhibitor | acid | | | | | | | | | |
| | Ascorbic | | | | | | | | | |
| | acid | | | | | | | | | |
| Silicon | MSA | 1.0 | | | 1.0 | | | 1.0 | 1.0 | 1.0 |
| film | Sulfamic | | | | | | | | | |
| etching | acid | | | | | | | | | |
| inhibitor | Ammonium | | | | | | | | | |
| | sulfamate | | | | | | | | | |
| Hydroxyl | Tetraethyl- | 18.8 | | | | 2.0 | | | | 8.2 |
| group- | ammonium | | | | | | | | | |
| containing | hydroxide | | | | | | | | | |
| basic | (TEAH) | | | | | | | | | |
| compound | | | | | | | | | | |
| pH regulator | Ammonium | | | | | | | 18.8 | | |
| (Buffer) | acetate | | | | | | | | | |
| Organic | Ethanolamine | 5.0 | | | | | 5.0 | 5.0 | 92.07 | 5.0 |
| solvent | (MEA) | | | | | | | | | |

Dipping results (Batch)

| Cu E/R [Å/min] | | 32.79 | 11.71 | 7.47 | 10.29 | 9.57 | 10.80 | 5.54 | 3.13 | 0.00 |
|---|---|---|---|---|---|---|---|---|---|---|
| Oxide E/R [Å/min] | | 0.14 | 0.22 | 0.32 | 0.25 | 0.03 | 0.30 | 0.02 | 0.31 | 0.03 |
| Oxide Roughness | | Decrease | No | Increase | No | No | No | No | Increase | Increase |
| (Increase/decrease | | | change | | change | change | change | change | | |
| before/after | | | | | | | | | | |
| evaluation) | | | | | | | | | | |
| Cleaning | Cu | Δ | X | X | X | X | X | X | Δ | Δ |
| power | Oxide | Δ | Δ | Δ | Δ | Δ | Δ | X | Δ | X |
| (Silica) | | | | | | | | | | |
| Cleaning | Cu | ◯ | X | X | X | X | ◯ | X | Δ | Δ |
| power | Oxide | ◯ | X | ◯ | ◯ | ◯ | Δ | X | X | X |
| (Organic) | | | | | | | | | | |

Brush Scrubbing Results

| Cu E/R [Å/min] | | 20.69 | −25.93 | 20.15 | 26.28 | 0.00 | 5.10 | 2.21 | 3.09 | 0.00 |
|---|---|---|---|---|---|---|---|---|---|---|
| Oxide E/R [Å/min] | | 0.00 | 0.05 | 0.05 | 0.06 | 0.01 | 0.00 | 0.01 | 0.43 | 0.15 |
| Oxide Roughness | | Decrease | No | No | No | No | No | No | No | No |
| (Increase/decrease | | | change | change | change | change | change | change | change | change |
| before/after | | | | | | | | | | |
| evaluation) | | | | | | | | | | |
| Cleaning | Cu | ◯ | X | X | X | X | X | X | Δ | Δ |
| power | Oxide | ◯ | Δ | ◯ | Δ | Δ | ◯ | X | Δ | X |
| (Silica) | | | | | | | | | | |
| Cleaning | Cu | ◯ | X | X | X | X | Δ | X | Δ | Δ |
| power | Oxide | ◯ | Δ | ◯ | ◯ | Δ | Δ | X | Δ | X |
| (Organic) | | | | | | | | | | |

As shown in Table 6, in Example 1, excellent performance was confirmed in cleaning power for a silica abrasive material, organic matter cleaning power, silicon oxide film etching rate, and silicon oxide film surface roughness. In Comparative Examples 1 to 5, it was confirmed that organic solvent MEA is effective in cleaning organic matter. However, it was confirmed that the cleaning power was reduced when the composition was not mixed according to Comparative Examples 1 to 5.

In addition, according to Comparative Example 6, which used MEA alone, it was confirmed to be poorly effective in cleaning the copper film surface. In Comparative Example 7, where ammonium acetate was used instead of TEAH, cleaning for the copper film and silicon oxide film was poor. According to Comparative Example 8, where TEAH was not used and the pH was adjusted to 11.5 with an alkanolamine, cleaning of the copper film and silicon oxide film was poor. In Comparative Example 9, where hydrogen peroxide was used as an etching agent such as citric acid, copper was not etched and the cleaning power for the silicon oxide film was very poor.

### Additional Test Examples

The same experiment as Example 1 was repeated except that the silicon oxide film (SiO) in Example 1 of Table 1 was replaced with a silicon carbon nitride film (SICN), and the evaluation results are shown in Table 7 below.

TABLE 7
Immersion evaluation results

| SICN E/R [Å/min] | | 0.02 |
|---|---|---|
| SICN Roughness | | No |
| (Increase/decrease | | change |
| before/after evaluation) | | |
| Cleaning power | SICN | Δ |
| (Silica) | | |
| Cleaning power | SICN | Δ |
| (Organic) | | |

Brush scrubbing evaluation results

| SICN E/R [Å/min] | | 0.33 |
|---|---|---|
| SICN Roughness | | No |
| (Increase/decrease | | change |
| before/after evaluation) | | |
| Cleaning power | SICN | ◯ |
| (Silica) | | |
| Cleaning power | SICN | ◯ |
| (Organic) | | |

As shown in Table 7, residues were effectively removed by brush scrubbing without etching the silicon carbon nitride film.

Accordingly, when the etching cleaning composition of the present invention is used as a post-polishing treatment composition, as a post-polishing treatment composition, due to anisotropic pattern etching ability and surface zeta potential repulsive cleaning ability thereof, by removing polishing residues generated when polishing surfaces that require hybrid bonding between joints in semiconductor and display manufacturing processes from abrasive materials, appropriate roughness for hybrid bonding may be provided without residual metal oxide films, the process may be shortened, and the effect of improving the bonding strength of the hybrid bonding process may be maximized.

1. An etching cleaning composition characterized by being a basic solution comprising an etching agent; a metal corrosion inhibitor; a silicon film etching inhibitor; a basic compound containing a hydroxyl group; and an alkanol amine compound.

2. The etching cleaning composition according to claim 1, wherein the etching cleaning composition has anisotropic pattern etching ability and surface zeta potential repulsive cleaning ability.

3. The etching cleaning composition according to claim 2, wherein the surface zeta potential repulsive cleaning ability is realized by making surface zeta potentials of a wafer and abrasive material negative (−).

4. The etching cleaning composition according to claim 1, wherein the etching agent is a compound containing a carboxyl group and having selective etching ability for copper, tungsten, or molybdenum.

5. The etching cleaning composition according to claim 1, wherein the metal corrosion inhibitor is a compound containing a functional group with strong reducing power and having corrosion inhibition ability of copper, tungsten, or molybdenum.

6. The etching cleaning composition according to claim 1, wherein the silicon film etching inhibitor is a compound containing a sulfonic acid group and preventing etching of a dielectric substance.

7. The etching cleaning composition according to claim 1, wherein the basic compound containing a hydroxyl group is a compound containing a hydroxyl group and adjusting pH of the etching cleaning composition to 8 or higher.

8. The etching cleaning composition according to claim 1, wherein, based on a total weight of the etching cleaning composition, the alkanol amine compound comprises one or more selected from propanolamine, ethanolamine, diethanolamine, triethanolamine, 2-2-(ethylamino)ethanol, 1-amino-2-propanol, 2-(methylamino)ethanol, N,N-dimethylethanolamine, 1,3-diamino-2-propanol, 2-amino-1,3-propanediol, and 2-amino-2-methyl-1-propanol in an amount of 0.1 to 10% by weight.

9. The etching cleaning composition according to claim 1, wherein the etching cleaning composition comprises one or more surfactants selected from a nonionic surfactant and an anionic surfactant.

10. The etching cleaning composition according to claim 1, wherein the etching cleaning composition has a pH of 8 to 14.

11. An etching cleaning method comprising etching and cleaning a wafer using the etching cleaning composition according to claim 1.

12. The etching cleaning method according to claim 11, wherein the etching and cleaning treatment is direct treatment, indirect treatment, or direct and indirect treatment, the direct treatment is continuous immersion or batch immersion, and the indirect treatment is padding treatment or brush treatment.

13. A hybrid bonding material, comprising:
preparing and polishing a semiconductor device or display device that requires hybrid bonding; and
etching and cleaning the polished wafer using the etching cleaning composition of claim 1,
wherein the metal electrode has an anisotropic etching pattern, and
change in surface roughness of the dielectric substance before and after etching cleaning is-0.01 nm or more.

14. The hybrid bonding material according to claim 13, wherein the metal electrode has a surface roughness of 0.1 to 1.2 nm.
